(19) United States
(12) Patent Application Publication
(10) Pub. No.: US 2024/0371762 A1
(43) Pub. Date: Nov. 7, 2024

(54) SEMICONDUCTOR DEVICE

(71) Applicant: SAMSUNG ELECTRONICS CO., LTD., Suwon-si (KR)

(72) Inventors: Woosung Park, Suwon-si (KR); Jiwon Park, Suwon-si (KR); Minseok Jo, Suwon-si (KR); Junyoup Lee, Suwon-si (KR); Jinyoung Choi, Suwon-si (KR)

(21) Appl. No.: 18/434,391

(22) Filed: Feb. 6, 2024

(30) Foreign Application Priority Data
May 4, 2023 (KR) 10-2023-0058103

(51) Int. Cl. H01L 23/528; H01L 29/06; H01L 29/423; H01L 29/775; H01L 29/78; H01L 29/786

(52) U.S. Cl. CPC H01L 23/5283; H01L 29/0673; H01L 29/42392; H01L 29/775; H01L 29/7851; H01L 29/78696

(57) ABSTRACT

An example semiconductor device includes an active region extending in a first direction and including first conductivity-type impurities, an ion doped region extending in the first direction in the active region and including second conductivity-type impurities, a gate structure extending in a second direction, intersecting the first direction, disposed on the active region and traversing the active region, a source/drain region on the active region on at least one side of the gate structure, a device isolation layer surrounding the active region, an interlayer insulating layer on the device isolation layer and covering the gate structure and the source/drain region, a vertical power structure extending in a third direction, perpendicular to the first and second directions, and passing through the device isolation layer and the interlayer insulating layer, and a bottom wiring connected to the vertical power structure and contacting a bottom surface of the active region.

### CROSS-REFERENCE TO RELATED APPLICATION

This application claims priority to Korean Patent Application No. 10-2023-0058103, filed on May 4, 2023, in the Korean Intellectual Property Office, the disclosure of which is incorporated herein by reference in its entirety.

### BACKGROUND

In line with growing demand for high performance, high speed, and/or multifunctionality of semiconductor devices, the degree of integration of semiconductor devices has increased. According to the trend for high integration of semiconductor devices, semiconductor devices having a back side power delivery network (BSPDN) structure in which a power rail is disposed on a rear surface of a wafer have been developed. As power is transmitted from the rear side, efforts have been made to develop semiconductor devices having improved reliability.

### SUMMARY

The present disclosure relates to semiconductor devices, including semiconductor devices having improved reliability.

In some implementations, a semiconductor device includes: an active region extending in a first direction and including first conductivity-type impurities; an ion doped region extending in the first direction in the active region and including second conductivity-type impurities; a gate structure extending in a second direction, intersecting the first direction, and traversing the active region on the active region; a source/drain region on the active region on at least one side of the gate structure; a device isolation layer surrounding the active region; an interlayer insulating layer on the device isolation layer and covering the gate structure and the source/drain region; a vertical power structure extending in a third direction, perpendicular to the first and second directions, and passing through the device isolation layer and the interlayer insulating layer; and a lower wiring connected to the vertical power structure and contacting a lower surface of the active region.

In some implementations, a semiconductor device includes: an active region extending in a first direction and including first impurities having a first conductivity-type; an ion doped region located in the active region and including second impurities; a gate structure extending in a second direction, intersecting the first direction, and traversing the active region on the active region; a source/drain region on the active region on at least one side of the gate structure; a device isolation layer surrounding the active region; an interlayer insulating layer on the device isolation layer and covering the gate structure and the source/drain region; a vertical power structure extending in a third direction, perpendicular to the first and second directions, and passing through the device isolation layer and the interlayer insulating layer; and a lower wiring contacting a lower surface of the vertical power structure and electrically connected to the vertical power structure.

In some implementations, a semiconductor device includes: an active region extending in a first direction and including first impurities; an ion doped region located in the active region and including second impurities; a gate structure extending in a second direction, intersecting the first direction, and traversing the active region on the active region; a source/drain region on the active region on at least one side of the gate structure; a vertical power structure extending in a third direction, perpendicular to the first and second directions, and electrically connected to the source/drain region; and a lower wiring disposed below the vertical power structure and electrically connected to the vertical power structure.

### BRIEF DESCRIPTION OF THE DRAWINGS

The above and other aspects, features, and advantages of the present concept will be more clearly understood from the following detailed description, taken in conjunction with the accompanying drawings.

FIG. 1 is a plan view illustrating an example of a semiconductor device.

FIGS. 2A to 2C are example cross-sectional views illustrating semiconductor devices.

FIGS. 3A and 3B are example cross-sectional views illustrating semiconductor devices.

FIGS. 4A to 4C are example cross-sectional views illustrating semiconductor devices.

FIG. 5 is a cross-sectional view illustrating an example of a semiconductor device.

FIG. 6 is a plan view illustrating another example of a semiconductor device.

FIG. 7 is a cross-sectional view illustrating an example of a semiconductor device.

FIG. 8 is a cross-sectional view illustrating another example of a semiconductor device.

FIGS. 9 to 14 are views illustrating a sequential process of an example of a method of manufacturing a semiconductor device.

FIGS. 15 and 16 are views illustrating a sequential process of another example of a method of manufacturing a semiconductor device.

FIGS. 17 and 18 are views illustrating a sequential process of another example of a method of manufacturing a semiconductor device.

### DETAILED DESCRIPTION

Hereinafter, implementations of the present disclosure will be described with reference to the accompanying drawings. Hereinafter, terms, such as ‘on,’ ‘upper portion, ‘upper surface, ‘below,’ ‘lower portion, ‘lower surface,’ and ‘side surface’ may be understood to be referred to, based on directions of the drawings, except that they are denoted by reference numerals to be referred to separately.

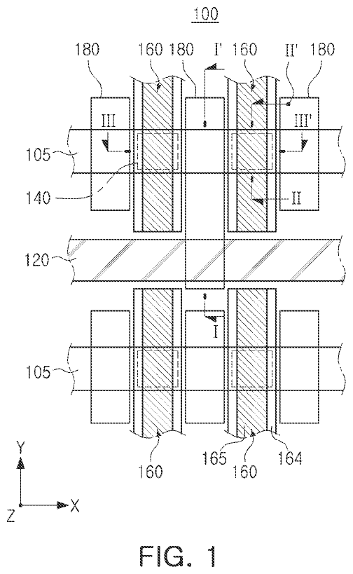

FIG. 1 is a plan view illustrating an example of a semiconductor device.

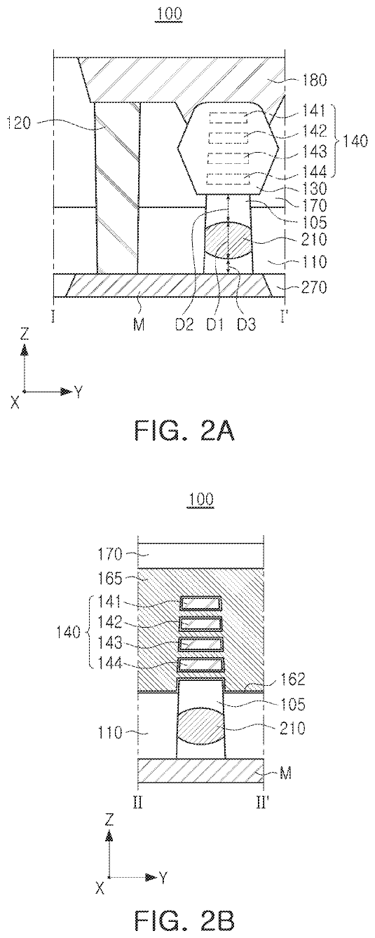

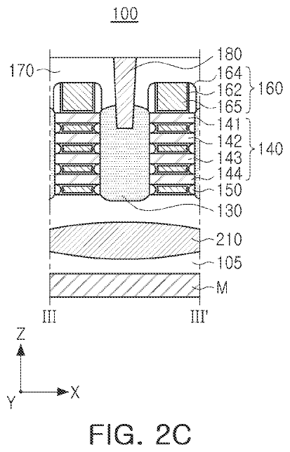

FIGS. 2A to 2C are example cross-sectional views illustrating a semiconductor device. FIGS. 2A, 2B, and 2C are cross-sectional views of the semiconductor device of FIG. 1 taken along lines I-I′, II-II′, and III-III′, respectively. For convenience of description, only some components of the semiconductor device are illustrated in FIG. 1.

Referring to FIGS. 1 to 2C, a semiconductor device 100 includes an active region 105, channel structures 140 including first to fourth channel layers 141, 142, 143, and 144 disposed to be vertically spaced apart from each other on the active region 105, gate structures 160 extending to cross the active region 105 and including gate electrodes 165, respectively, source/drain regions 130 contacting the channel structures 140, and a vertical power structure 120 electrically connected to the source/drain region 130. In the implementations illustrated herein, the phrase source/drain region may be understood to mean a source terminal region, a drain terminal region, or a source and drain terminal region of a transistor. An ion doped region 210 may be located in the active region 105. The semiconductor device 100 may further include contact structures 180 connected to the source/drain regions 130 and a lower wiring M. The semiconductor device 100 may further include a device isolation layer 110, internal spacer layers 150, an interlayer insulating layer 170, and a rear insulating layer 270. The gate structures 160 may include gate dielectric layers 162, gate spacer layers 164, and gate electrodes 165, respectively.

The active region 105 is disposed to extend in a first direction, for example, an X-direction. The active region 105 may be a region defined at a predetermined depth from an upper surface of a portion of a substrate including a semiconductor material. The active region 105 may be formed of a portion of the substrate or may include an epitaxial layer grown from the substrate. The substrate may be removed from below the active region 105 during a manufacturing process. The active regions 105 may include active fins protruding upwardly, respectively. The active region 105 may form an active structure in which a channel region of a transistor is formed together with the channel structures 140. Each active region 105 may include an impurity region. The impurity region may form at least a portion of a well region of a transistor. The active region 105 may include a semiconductor material, such as a group IV semiconductor, a group III-V compound semiconductor, or a group II-VI compound semiconductor. For example, the group IV semiconductor may include silicon, germanium, or silicon-germanium. The active region 105 may be a layer formed by patterning a bulk wafer, an epitaxial layer, a silicon on insulator (SOI) layer, or a semiconductor on insulator (SeOI) layer.

An ion doped region 210 may be located in the active region 105. In this case, the active region 105 may include first impurities, and the ion doped region 210 may include second impurities. In this case, the first impurities may have a first conductivity-type and the second impurities may have a second conductivity-type. The first conductivity-type may be P-type or N-type, and the second conductivity-type may be N-type or P-type, different from the first conductivity-type. When the first conductivity-type is P-type, the first conductivity-type impurities include at least one of boron (B), aluminum (Al), gallium (Ga), and indium (In), and in this case, the second conductivity-type impurities, that is, N-type impurities, include at least one of phosphorus (P), arsenic (As), and antimony (Sb). Conversely, when the first conductivity-type is N-type, the first conductivity-type impurities include at least one of phosphorus (P), arsenic (As), and antimony (Sb), and in this case, the second conductivity-type impurities, that is, N-type impurities, include at least one of boron (B), aluminum (Al), gallium (Ga), and indium (In).

The ion doped region 210 may be spaced apart from the upper and lower surfaces of the active region 105. A distance D2 at which the ion doped region 210 is spaced apart from an upper surface of the active region may be greater than a distance D3 at which the ion doped region 210 is spaced apart from a lower surface of the active region. A thickness D1 of the ion doped region may be greater than the separation distances D2 and D3, but the size and size relationship of the thickness D1 and the separation distances D2 and D3 may vary in some implementations. An upper end of the ion doped region 210 may be located on a level lower than an interface between the device isolation layer 110 and the interlayer insulating layer 170.

An N-P-N junction or a P-N-P junction is formed among the active region 105, the ion doped region 210, and the active region 105, and the active region 105 and the lower wiring M may be electrically insulated by a reverse bias operation.

The device isolation layer 110 is located between adjacent active regions 105 in a Y-direction. Upper surfaces of the active region 105 may be located on a level higher than that of upper surfaces of the device isolation layer 110. On at least one side of the gate structures 160, the active region 105 may be partially recessed, and the source/drain region 130 may be disposed in the recess regions.

The device isolation layer 110 fills a portion between the active regions 105 and define the active regions 105 in a substrate 101. The device isolation layer 110 may be formed by, for example, a shallow trench isolation (STI) process. The device isolation layer 110 may expose the upper surface of the active region 105 or partially expose an upper portion of the active region 105. The device isolation layer 110 may be formed of an insulating material. The device isolation layer 110 may include, for example, an oxide, a nitride, or combinations thereof.

The rear insulating layer 270 is disposed to cover the lower surface of the active region 105 and a lower surface of the device isolation layer 110. The rear insulating layer 270 may be disposed on the lower surfaces of the active region 105, the vertical power structure 120, and/or the device isolation layer 110.

A thickness of the rear insulating layer 270 may be variously changed in some implementations. The rear insulating layer 270 may include an insulating material, such as an oxide, a nitride, or combinations thereof. In some implementations, the rear insulating layer 270 may include, for example, a native oxide of the substrate.

The gate structures 160 are disposed on the active region 105 to cross the active region 105 and extend in the second direction, for example, the Y-direction. Channel regions of transistors may be formed in the channel structure 140 and the active region 105 crossing the gate electrodes 165 of the gate structures 160. Some of the gate structures 160 may be spaced apart from each other while being disposed on a straight line in the Y-direction.

The gate structures 160 include gate dielectric layers 162, gate spacer layers 164, and gate electrodes 165, respectively. In some implementations, the gate structures 160 may further include capping layers on upper surfaces of the gate electrodes 165, respectively. Alternatively, a portion of the interlayer insulating layer 170 on the gate structure 160 may be referred to as a gate capping layer.

The gate dielectric layers 162 are disposed between the active region 105 and the gate electrode 165 and between the channel structure 140 and the gate electrode 165, and may cover at least portions of the surfaces of the gate electrode 165. For example, the gate dielectric layers 162 may be disposed to surround all surfaces except for the uppermost surface of the gate electrode 165. The gate dielectric layers 162 may extend between the gate electrode 165 and the gate spacer layers 164, but are not limited thereto. The gate dielectric layer 162 may include an oxide, a nitride, or a high-κ material. The high-κ material may refer to a dielectric material having a higher dielectric constant than silicon oxide (SiO₂). The high-κ material may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). According to some implementations, the gate dielectric layer 162 may have a multilayer structure.

The gate electrode 165 include a conductive material, for example, a metal nitride, such as titanium nitride (TiN), tantalum nitride (TaN), or tungsten nitride (WN), and/or a metal material, such as aluminum (Al), tungsten. (W), or molybdenum (Mo), or a semiconductor material, such as doped polysilicon. According to some implementations, the gate electrode 165 may have a multilayer structure.

The gate spacer layers 164 are disposed on both side surfaces of the gate electrode 165 on the channel structure 140. The gate spacer layers 164 may insulate the source/drain regions 130 and the gate electrodes 165 from each other. According to some implementations, a shape of an upper end of the gate spacer layers 164 may be variously changed, and the gate spacer layers 164 may have a multilayer structure. The gate spacer layers 164 may include at least one of oxide, nitride, and oxynitride, and may be formed of, for example, a low-κ film.

The channel structures 140 are disposed on the active region 105 in regions in which the active region 105 crosses the gate structures 160. Each of the channel structures 140 may include first to fourth channel layers 141, 142, 143, and 144 that are two or more channel layers spaced apart from each other in a Z-direction. That is, a plurality of channel layers 141, 142, 143, and 144 spaced apart from each other in the third direction (the Z-direction), perpendicular to the first direction (the X-direction) and the second direction (the Y-direction), on the active region 105 and surrounded by the gate structure 160 may be further provided. The channel structures 140 may be connected to the source/drain regions 130. The channel structures 140 may have a width equal to or smaller than that of the active region 105 in the Y-direction, and may have a width equal to or similar to that of the gate structures 160 in the X-direction. In a cross-section in the Y-direction, a lower channel layer, among the first to fourth channel layers 141, 142, 143, and 144, may have a width equal to or larger than that of an upper channel layer. In some implementations, the channel structures 140 may have a smaller width than that of the gate structures 160 so that side surfaces of the channel structures 140 are located below the gate structures 160 in the X-direction.

The channel structures 140 are formed of a semiconductor material, and may include, for example, at least one of silicon (Si), silicon germanium (SiGe), and germanium (Ge). The channel structures 140 may be formed of, for example, the same material as that of the active region 105. The number and shape of the channel layers constituting one channel structure 140 may be variously changed in some implementations.

In the semiconductor device 100, the gate electrode 165 is disposed between the active region 105 and the channel structures 140 and between the first to fourth channel layers 141, 142, 143, and 144 of the channel structures 140, and on the channel structures 140. Accordingly, the semiconductor device 100 may include a multi bridge channel FET (MBCFET™) Structure transistor, which is a gate-all-around type field effect transistor. However, in some implementations, the semiconductor device 100 may not include the channel structures 140 and may have, for example, a FinFET structure.

The source/drain regions 130 are disposed on both sides of the gate structures 160 to contact the channel structures 140. The source/drain regions 130 may be disposed in regions in which an upper portion of the active region 105 is partially recessed. As illustrated in FIG. 2A, power may be applied to the source/drain region 130 through the contact structure 180, the lower wiring M, and the vertical power structure 120.

The upper surfaces of the source/drain region 130 may be located on a level the same as or similar to that of the lower surfaces of the gate structures 160 on the channel structures 140, but the level of the upper surfaces of the source/drain region 130 may be variously changed in some implementations. The source/drain region 130 may have a polygonal shape as illustrated in FIG. 2A or an elliptical shape in a cross-section in the Y-direction, but is not limited to the illustrated shape. The source/drain region 130 may include a semiconductor material, for example, silicon (Si) and/or germanium (Ge), and may further include impurities.

The internal spacer layers 150 are disposed parallel to the gate electrode 165 between the first to fourth channel layers 141, 142, 143, and 144 in the Z-direction. The gate electrode 165 may be stably spaced apart and electrically separated from the source/drain regions 130 by the internal spacer layers 150. A side surface of the internal spacer layers 150 facing the gate electrode 165 may be inwardly convexly rounded toward the gate electrode 165, but is not limited thereto. The internal spacer layers 150 may include at least one of oxide, nitride, and oxynitride, and may be formed of, for example, a low-κ film. However, in some implementations, the internal spacer layers 150 may be omitted.

The contact structures 180 are disposed on the source/drain region 130. The contact structures 180 may pass through the interlayer insulating layer 170 and be connected to the source/drain regions 130. The contact structures 180 may have side surfaces inclined to decrease in width toward the active region 105 due to an aspect ratio, but are not limited thereto. The contact structures 180 may partially recess the source/drain regions 130 and may be disposed to contact portions of surfaces including upper surfaces of the source/drain regions 130. Accordingly, a portion of the contact structure 180 may be disposed to overlap a portion of the source/drain region 130 in the first direction (the X-direction). Separate contact structures 180 may be further disposed on the gate electrodes 165 in regions not illustrated.

Each of the contact structures 180 may include a metal silicide layer located at a lower end thereof, and may further include a barrier layer disposed on the metal silicide layer and sidewalls. The barrier layer may include, for example, a metal nitride, such as titanium nitride (TiN), tantalum nitride (TaN), or tungsten nitride (WN). The contact structures 180 may include, for example, a metal material, such as aluminum (Al), tungsten (W), or molybdenum (Mo). In some implementations, the number and arrangement of conductive layers constituting the contact structures 180 may be variously changed.

Among the contact structures 180, the contact structure 180 connected to the source/drain region 130 is relatively elongate in the Y-direction to be connected to the vertical power structure 120 as well. The contact structure 180 may be connected to the upper surface of the vertical power structure 120, but is not limited thereto. In some implementations, the contact structure 180 may be connected to a side surface of the vertical power structure 120 or may be connected to an upper surface and a side surface of the vertical power structure 120. In some implementations, the contact structure 180 and vertical power structure 120 may be integrally formed.

The vertical power structure 120 are arranged to connect the contact structure 180 to the lower wiring M. As illustrated in FIG. 2A, the vertical power structure 120 may be disposed between adjacent gate structures 160 in the Y-direction. The vertical power structure 120 may be disposed to pass through the interlayer insulating layer 170 and the device isolation layer 110.

As illustrated in FIG. 1, the vertical power structure 120 is disposed in a region in which the gate structures 160 are spaced apart from each other in the Y-direction and/or in a region overlapping the region in the X-direction. The vertical power structure 120 may be spaced apart from the gate structures 160 in the Y-direction. Accordingly, the vertical power structure 120 may not overlap the gate structures 160 in the X-direction. The vertical power structure 120 may extend in a line shape in the X-direction, but the extended length is not limited to that illustrated in FIG. 1. In some implementations, the vertical power structure 120 has an elliptical or circular shape in plan view. In some implementations, the vertical power structure 120 does not extend between gate structures 160 adjacent to each other in the Y-direction.

In the present implementation, the vertical power structure 120 is connected to the contact structure 180 through an upper surface thereof and connected to the lower wiring M through a lower surface thereof. The upper surface or upper end of the vertical power structure 120 may be located on a level the same as or similar to that of the upper surface or the upper end of the source/drain region 130. A lower end of the vertical power structure 120 may be located on a level lower than a level of the lower surface of the source/drain region 130. The vertical power structure 120 may have side surfaces inclined to decrease in width toward the rear insulating layer 270 due to an aspect ratio, but is not limited thereto.

The vertical power structure 120 include a conductive material, for example, a metal material, such as tungsten (W), molybdenum (Mo), copper (Cu), or cobalt (Co).

The lower wiring M forms a back side power delivery network (BSPDN) that applies power or ground voltage, and may be referred to as a rear power rail or an embedded power rail. For example, the lower wiring M may be an embedded wiring line extending in one direction, for example, in the X-direction below the vertical power structure 120, but the shape of the lower wiring M is not limited thereto. For example, in some implementations, the lower wiring M may include a via region and a line region. A width of the lower wiring M may continuously increase downwardly, but is not limited thereto.

The semiconductor device 100 is packaged by reversing the structure of FIGS. 2A to 2C so that the lower wiring M is located on the top, but the packaging form of the semiconductor device 100 is not limited thereto. Since the semiconductor device 100 includes the lower wiring M disposed below the source/drain region 130, the degree of integration may be improved. In addition, since the entire substrate is removed below the active region 105, the substrate thickness control problem may be solved, and since a P-N-P junction or an N-P-N junction is formed between the active region 105—the ion doped region 210—the active region 105, when the lower wiring M applies an electrical signal to the vertical power structure 120, a reverse bias voltage may be applied to the active region 105 and the ion doped region 210, so that the lower wiring M may be electrically insulated from the active region 105 even if the former is in contact with the latter. Accordingly, a semiconductor device having improved reliability may be provided without a separate insulating layer.

In the description of the following implementations, the same contents as those described above will be omitted.

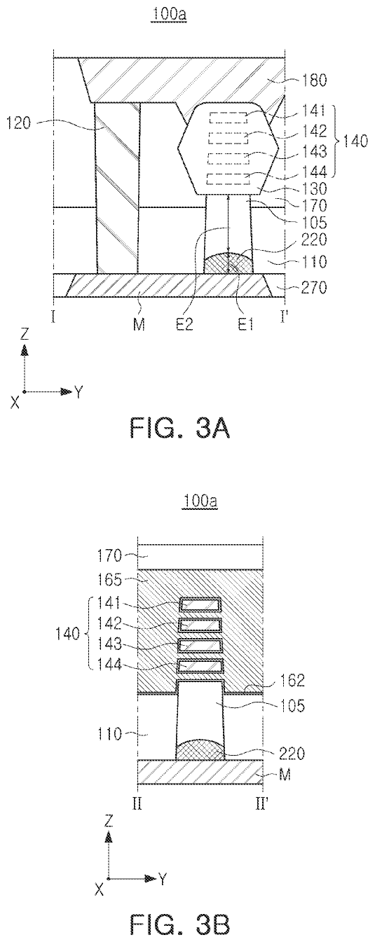

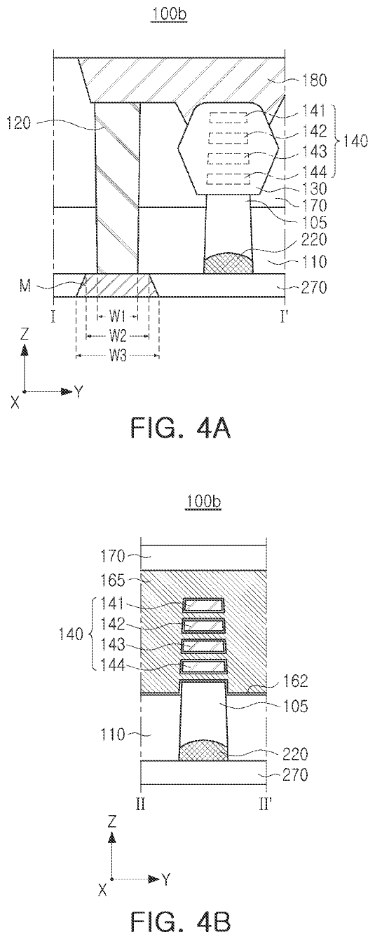

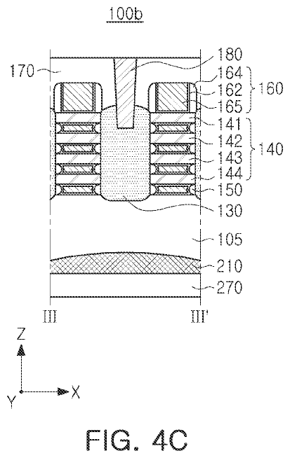

FIGS. 3A to 4C are example cross-sectional views illustrating semiconductor devices.

Referring to FIGS. 3A and 3B, in a semiconductor device 100a, an insulating ion doped region 220, an insulating region, are disposed in the active region 105. The lower wiring M may contact the lower surface of the active region 105. The insulating ion doped region 220 may be disposed at a lower end of the active region 105, and in this case, the insulating ion doped region 220 may contact the lower wiring M. The insulating ion doped region 220 may include ions having low electrical conductivity, and thus, the active region 105 may be electrically insulated from the lower wiring M. The insulating ion doped region 220 may include at least one of carbon (C), oxygen (O), and nitrogen (N). A thickness E1 of the insulating ion doped region 220 may be less than a distance E2 at which the insulating ion doped region 220 is spaced apart from the upper surface of the active region 105, but is not limited thereto.

Referring to FIGS. 4A to 4C, in a semiconductor device 100b, the lower wiring M contacts the lower surface of the vertical power structure 120, but may not contact the lower surface of the active region 105 or the insulating ion doped region 220. A width W2 of the upper end of the lower wiring M may be greater than a width W1 of the lower end of the vertical power structure 120 and may be less than a width W3 of the lower end of the lower wiring M. In some implementations, the width W2 of the upper end of the lower wiring M may be large enough for the upper surface of the lower wiring M to contact the active region 105 or the insulating ion doped region 220.

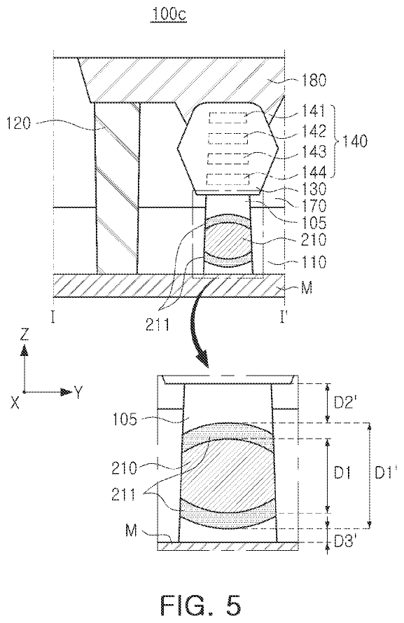

FIG. 5 is a cross-sectional view of an example of a semiconductor device and an enlarged view of the active region 105.

Referring to FIG. 5, in a semiconductor device 100c, an expanded ion doped region 211 in contact with the ion doped region 210 is disposed in the active region 105. The expanded ion doped region 211 may be spaced apart from the upper and lower surfaces of the active region 105, and the expanded ion doped region 211 may contact upper and lower ends of the ion doped region 210. When the active region 105 includes first conductivity-type impurities and the ion doped region 210 includes second conductivity-type impurities, the expanded ion doped region 211 may include the first conductivity-type impurities as those of the active region 105. In this case, a concentration of first conductivity-type impurities in the expanded ion doped region 211 may be greater than a concentration of first conductivity-type impurities in the active region 105. When the first conductivity-type of the active region 105 is P-type, the first conductivity-type impurities of the expanded ion doped region 211 may include at least one of boron (B), aluminum (Al), gallium (Ga), and indium (In), and the concentration thereof may be greater than the concentration of boron (B), aluminum (Al), gallium (Ga), or indium (In) in the active region 105. When the first conductivity-type is N-type, the first conductivity-type impurities of the expanded ion doped region 211 may include at least one of phosphorus (P), arsenic (As), and antimony (Sb), and their concentrations may be greater than the concentration of phosphorus (P), arsenic (As), or antimony (Sb) in the active region 105.

By forming a P-N-P or N-P-N junction between the expanded ion doped region 211—the ion doped region 210—the expanded ion doped region 211, a junction stronger than the P-N-P junction or N-P-N junction between the active region 105—the ion doped region 210—the active region 105 may be formed.

A level difference D1′ between an upper end and a lower end of the expanded ion doped region 211 may be greater than a thickness D1 of the expanded ion region. A distance D2′ at which the expanded ion doped region 211 is spaced apart from the upper end of the active region 105 may be greater than a distance D3′ at which the expanded ion doped region 211 is spaced apart from the lower end of the active region 105. The size and size relationship of the level difference D1′ and the separation distances D2′ and D3′ may be variously changed in some implementations.

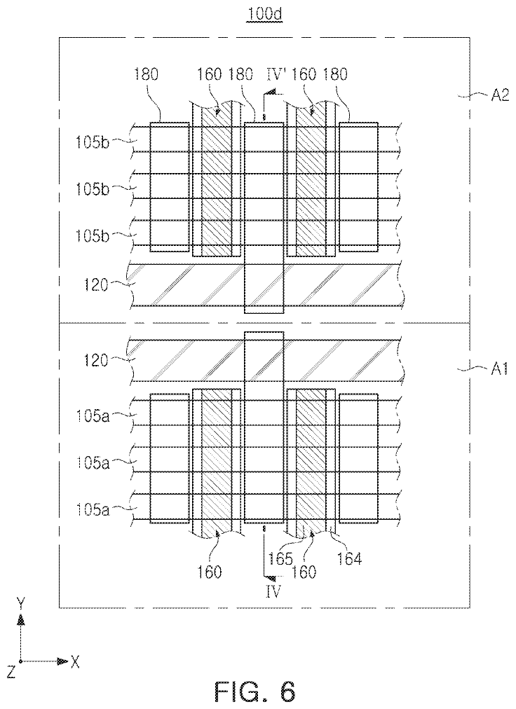

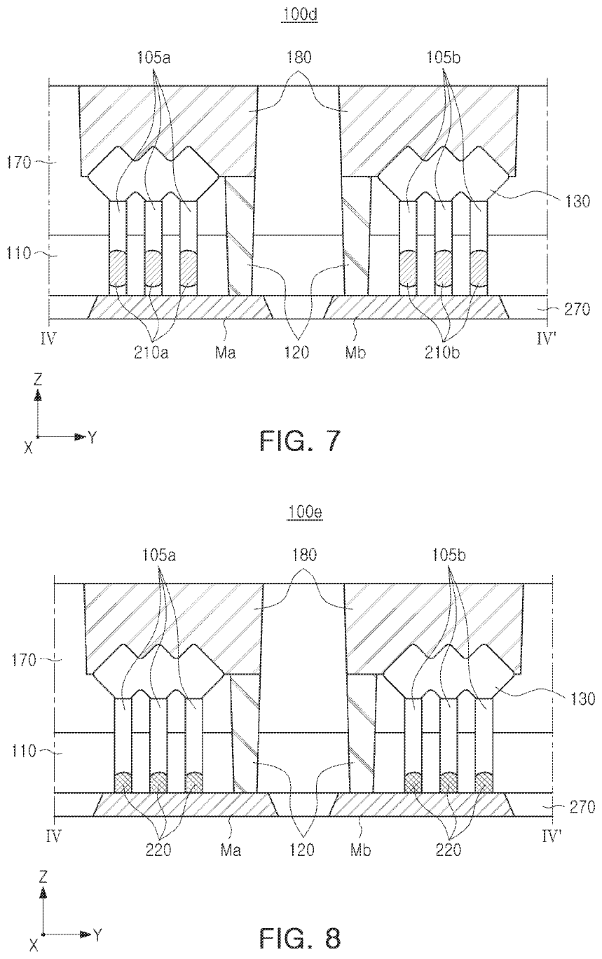

FIGS. 6 and 7 are plan and cross-sectional views illustrating another example of a semiconductor device.

First, referring to FIG. 6, a semiconductor device 100d is a FinFET device and may include a first region A1 and a second region A2. First active regions 105a may be disposed in the first region A1, and second active regions 105b may be disposed in the second region A2. The first active regions 105a may include first conductivity-type impurities, and the second active regions 105b may include second conductivity-type impurities. The first region A1 and the second region A2 may be adjacent to or separated from each other.

The vertical power structure 120 is disposed in at least one of the first region A1 and the second region A2. As illustrated in FIG. 6, the vertical power structure 120 may be disposed in both the first region A1 and the second region A2, and a position in which the vertical power structure 120 is disposed in each region may vary. In FIG. 6, it is illustrated that the vertical power structures 120 of each region are disposed to be adjacent to each other, but without being limited thereto, the vertical power structures 120 may be variously located, that is, disposed at the edge of each region or at the same location in each region.

Referring to FIG. 7, in a semiconductor device 100d, first ion doped regions 210a are disposed in the first active regions 105a, and second ion doped regions 210b may be disposed in the second active regions 105b. The first active regions 105a may include first conductivity-type impurities, and the second active regions 105b may include second conductivity-type impurities. The first ion doped regions 210a may include second conductivity-type impurities, and the second ion doped regions 210b may include first conductivity-type impurities.

In the implementation of FIG. 5, first expanded ion doped regions is further disposed to contact the first ion doped regions 210a in the first active regions 105a, and second expanded ion doped regions may be further disposed to contact the second ion doped regions 210b in the second active regions 105b. In this case, the first expanded ion doped regions may include first conductivity-type impurities of the first ion doped regions 210a, and the second expanded ion doped regions may include second conductivity-type impurities.

When the first conductivity-type is P-type, N-type second conductivity-type impurities in the first ion doped regions 210a include at least one of phosphorus (P), arsenic (As), and antimony (Sb), and the P-type first conductivity-type impurities in the second ion doped regions 210b include at least one of boron (B), aluminum (Al), gallium (Ga), and indium (In).

The first lower wiring Ma may be disposed to contact lower surfaces of the first active regions 105a in the first region A1. When the first lower wiring Ma applies an electrical signal to the vertical power structure 120, a reverse bias voltage may be applied to the first active regions 105a and the first ion doped regions 210a, so that the first lower wiring Ma may be electrically insulated from the first active regions 105a even if the former contacts the latter. The second lower wiring Mb may be disposed to contact lower surfaces of the second active regions 105b in the second region A2. When the second lower wiring Mb applies an electrical signal to the vertical power structure 120, a reverse bias voltage may be applied to the second active regions 105b and the second ion doped regions 210b, so that the second lower wiring Mb may be electrically insulated from the second active region 105b even if the former contacts the latter.

FIG. 8 is a cross-sectional view illustrating another example of a semiconductor device.

Referring to FIG. 8, in a semiconductor device 100e, an insulating ion doped region 220 is disposed in the first and second active regions 105a and 105b. The insulating ion doped region 220 may be disposed at a lower end of the first and second active regions 105a and 105b and may contact first and second lower wirings Ma and Mb.

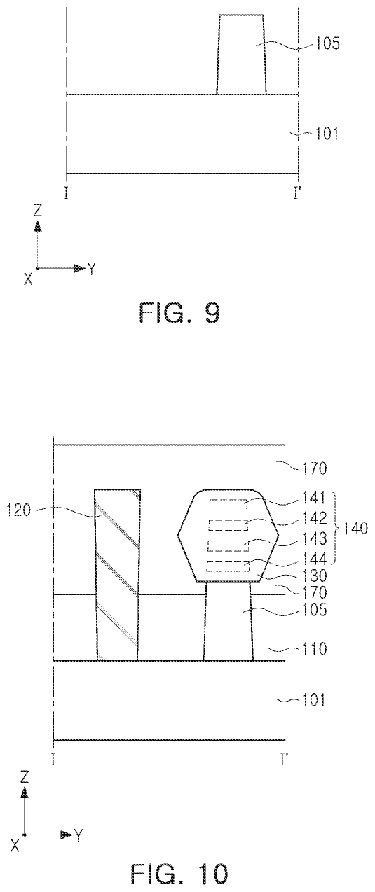

FIGS. 9 to 14 are views illustrating a sequential process of an example of a method of manufacturing a semiconductor device. FIGS. 9 to 14 illustrate an implementation of a manufacturing method for manufacturing the semiconductor device of FIGS. 1 to 2C, and show a cross-section corresponding to FIG. 2A.

Referring to FIG. 9, the substrate 101 includes the active region 105 disposed thereon. However, depending on a description method, the active region 105 may be described as a separate component from the substrate 101. The substrate 101 may include a semiconductor material, such as a Group IV semiconductor, a Group III-V compound semiconductor, or a Group II-VI compound semiconductor. For example, the group IV semiconductor may include silicon, germanium, or silicon-germanium. The active region 105 may be a layer formed by patterning a bulk wafer, an epitaxial layer, a silicon-on-insulator (SOI) layer, or a semiconductor-on-insulator (SeOI) layer.

Referring to FIG. 10, active structures including first to fourth channel layers 141, 142, 143, and 144 and active regions 105 are formed, and source/drain regions 130 and vertical power structure 120 are formed.

The first to fourth channel layers 141, 142, 143, and 144 include a semiconductor material including at least one of silicon (Si), silicon germanium (SiGe), and germanium (Ge), but may include different materials, or may or may not include impurities.

The active structures may be formed in a line shape extending in one direction, for example, the X-direction, and may be formed to be spaced apart from each other in the Y-direction. Depending on the aspect ratio, the side surfaces of the active structures may have an inclined shape such that a width thereof increases, while facing downwardly.

The device isolation layer 110 is formed on the upper surface of the substrate 101 so that the active regions 105 protrude. In this case, an upper surface of the device isolation layer 110 may be lower than upper surfaces of the active regions 105.

The source/drain regions 130 are formed by growing from side surfaces of the active regions 105 and the channel structures 140 by, for example, a selective epitaxial process. The source/drain regions 130 may include impurities by in-situ doping, and may include a plurality of layers having different doping elements and/or doping concentrations. In this operation, the gate structure 160 (please refer to FIG. 2C) may also be formed in a region (not shown).

After a hole extending into the substrate 101 through the interlayer insulating layer 170 is formed between adjacent source/drain regions 130 in the Y-direction, an insulating layer and a conductive layer are sequentially formed in the hole to form the vertical power structure 120. Thereafter, the interlayer insulating layer 170 may be further formed.

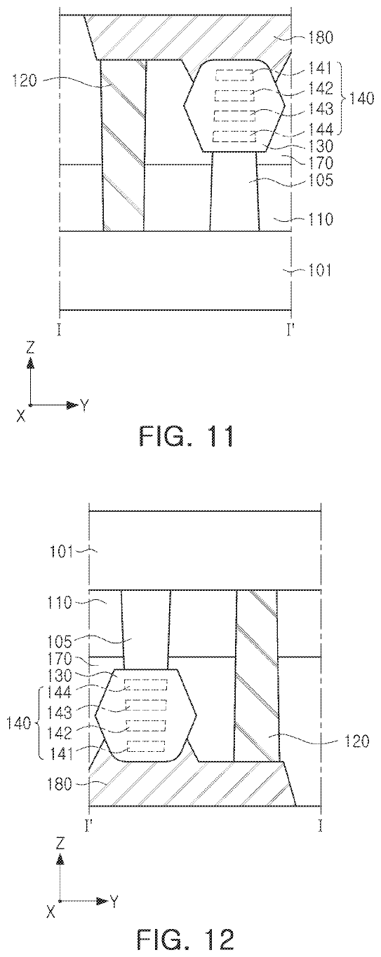

Referring to FIG. 11, the contact structure 180 is formed by partially removing the interlayer insulating layer 170 and then depositing a conductive material. The contact structure 180 may be formed and a portion of an upper end of the source/drain region 130 may be recessed.

The entire structure formed with reference to FIGS. 9 to 11 is not limited to the illustrated configuration. For example, an upper via, an upper insulating layer, and an upper wiring may be disposed on the top of the contact structure 180. In the following drawings, including FIG. 12, for better understanding, it is illustrated that the entire structure illustrated in FIG. 11 is rotated.

Referring to FIG. 12, a subsequent manufacturing process is carried out by turning the substrate 101 over.

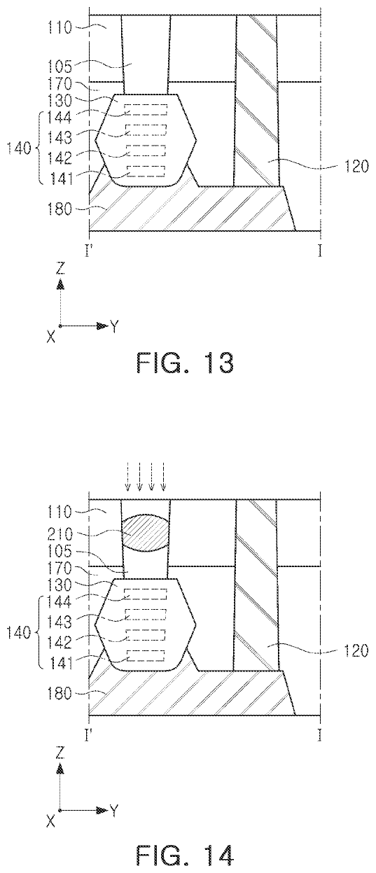

Referring to FIG. 13, the substrate 101 is etched and removed. The substrate 101 may be thinned and removed by, for example, a lapping, grinding, or polishing process. As the substrate 101 is removed, a lower surface of the active region 105, a lower surface of the device isolation layer 110, and an upper surface of the vertical power structure 120 may be exposed.

Referring to FIG. 14, the ion doped region 210 is formed in the active region 105. The ion doped region 210 may be formed by an ion implantation process. A blocking layer may be disposed on the device isolation layer 110 and the vertical power structure 120 to form the ion doped region 210 in the active region 105. When the active region 105 includes first conductivity-type impurities, the ion doped region 210 may include second conductivity-type impurities.

Next, referring to FIG. 2A together, the lower wiring M is disposed on the exposed lower surfaces of the device isolation layer 110, the active region 105, and the vertical power structure 120. According to an implementation, a rear insulating layer 270 may be formed on the exposed lower surfaces of the device isolation layer 110, the active region 105, and the vertical power structure 120, and thereafter, the rear insulating layer 270 may be etched and the lower wiring M may be disposed.

The semiconductor device 100 may be packaged in a state in which the lower wiring M is located in an upper portion thereof, but is not limited thereto.

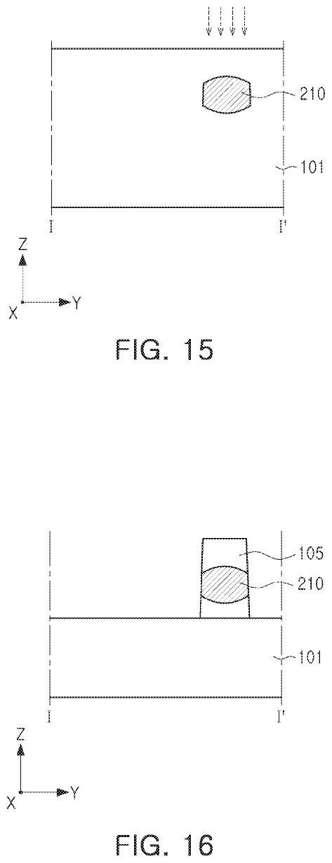

FIGS. 15 and 16 are views illustrating a sequential process of another example of a method of manufacturing a semiconductor device. A manufacturing method, different from the manufacturing method in FIGS. 9 to 14, is described, and a cross-section corresponding to FIG. 2A is illustrated.

Referring to FIG. 15, the ion doped region 210 is formed in the substrate 101 before the active region 105 is formed. The ion doped region 210 may be formed by an ion implantation process, and a mask (a blocking layer) may be used to form the ion doped region 210 in a specific region.

Referring to FIG. 16, after the ion doped region 210 is formed, the substrate 101 may be etched to form the active region 105 including the ion doped region 210. A manufacturing method of components other than the order of forming the ion doped region 210 may be the same as those of FIGS. 9 to 14.

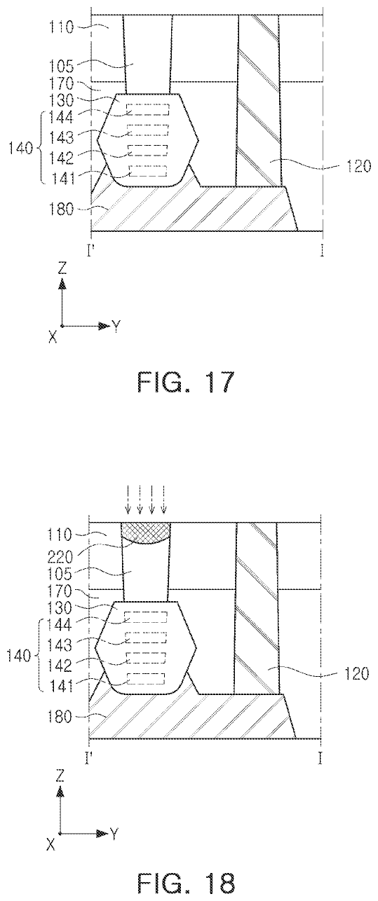

FIGS. 17 and 18 are views illustrating a sequential process of another example of a method of manufacturing a semiconductor device. FIGS. 17 and 18 illustrate cross-sections corresponding to FIG. 4A.

Referring to FIG. 17, the semiconductor device 100a of FIG. 4A is manufactured in the same manner as the manufacturing method of FIGS. 9 to 13.

Referring to FIG. 18, the insulating ion doped region 220 is formed in a state in which the lower surface of the active region 105 is exposed. The insulating ion doped region 220 may be formed by an ion implantation process, and a mask (a blocking layer) may be disposed on the device isolation layer 110 and the vertical power structure 120 so that the insulating ion doped region may be formed in the active region 105.

Next, referring to FIG. 4A together, the lower wiring M is disposed on the exposed surfaces of the device isolation layer 110, the active region 105, and the vertical power structure 120. According to an implementation, the rear insulating layer 270 may be formed on the exposed lower surfaces of the device isolation layer 110, the active region 105, and the vertical power structure 120, and thereafter, the rear insulating layer 270 may be etched and the lower wiring M may be disposed.

By disposing the doped region in the active region, the active region and the lower wiring may be electrically insulated from each other even if they are in contact with each other, thereby providing the semiconductor device having improved reliability.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While implementations have been illustrated and described above, it will be apparent to those skilled in the art that modifications and variations could be made without departing from the scope of the present concept as defined by the appended claims.

What is claimed is:

1. A semiconductor device comprising:
an active region extending in a first direction and including first conductivity-type impurities;
an ion doped region in the active region and extending in the first direction, wherein the ion doped region includes second conductivity-type impurities;
a gate structure extending in a second direction, the second direction intersecting the first direction, wherein the gate structure is disposed on the active region and traverses the active region;
a source/drain region on the active region on at least one side of the gate structure;
a device isolation layer surrounding the active region;
an interlayer insulating layer on the device isolation layer and covering the gate structure and the source/drain region;
a vertical power structure extending in a third direction, the third direction perpendicular to the first and second directions, wherein the vertical power structure passes through the device isolation layer and the interlayer insulating layer; and
a bottom wiring connected to the vertical power structure and contacting a bottom surface of the active region.

2. The semiconductor device of claim 1, wherein the ion doped region is separated from a top surface and the bottom surface of the active region.

3. The semiconductor device of claim 2, wherein a distance at which the ion doped region is separated from the top surface of the active region is greater than a distance at which the ion doped region is separated from the bottom surface of the active region.

4. The semiconductor device of claim 1, wherein
the first conductivity-type impurities have a first conductivity-type, and the second conductivity-type impurities have a second conductivity-type,
the first conductivity-type is P-type, the second conductivity-type is N-type, and
the second conductivity-type impurities include at least one of phosphorus (P), arsenic (As), and antimony (Sb).

5. The semiconductor device of claim 1, wherein
the first conductivity-type impurities have a first conductivity-type, and the second conductivity-type impurities have a second conductivity-type,
the first conductivity-type is N-type, the second conductivity-type is P-type, and
the second conductivity-type impurities include at least one of boron (B), aluminum (Al), gallium (Ga), and indium (In).

6. The semiconductor device of claim 1, wherein a top end of the ion doped region is lower than an interface between the device isolation layer and the interlayer insulating layer.

7. The semiconductor device of claim 1, further comprising an expanded ion doped region in contact with the ion doped region in the active region, the expanded ion doped region including the first conductivity-type impurities.

8. The semiconductor device of claim 7, wherein a concentration of the first conductivity-type impurities in the expanded ion doped region is higher than a concentration of the first conductivity-type impurities in the active region.

9. The semiconductor device of claim 7, wherein the expanded ion doped region is separated from a top surface and the bottom surface of the active region.

10. The semiconductor device of claim 9, wherein a distance at which the expanded ion doped region is separated from the top surface of the active region is greater than a distance at which the expanded ion doped region is separated from the bottom surface of the active region.

11. The semiconductor device of claim 1, further comprising a plurality of channel layers separated in the third direction on the active region and surrounded by the gate structure.

12. A semiconductor device comprising:
an active region extending in a first direction and including first impurities having a first conductivity-type;
an ion doped region located in the active region and including second impurities;
a gate structure extending in a second direction, the second direction intersecting the first direction, wherein the gate structure is disposed on the active region and traverses the active region;
a source/drain region on the active region on at least one side of the gate structure;
a device isolation layer surrounding the active region;
an interlayer insulating layer on the device isolation layer and covering the gate structure and the source/drain region;
a vertical power structure extending in a third direction, the third direction perpendicular to the first and second directions, wherein the vertical power structure passes through the device isolation layer and the interlayer insulating layer; and
a bottom wiring contacting a bottom surface of the vertical power structure and electrically connected to the vertical power structure.

13. The semiconductor device of claim 12, wherein the ion doped region is an insulating region.

14. The semiconductor device of claim 13, wherein the second impurities include at least one of carbon (C), oxygen (O), and nitrogen (N).

15. The semiconductor device of claim 14, wherein the ion doped region is disposed at a bottom end of the active region.

16. The semiconductor device of claim 15, wherein the bottom wiring contacts the ion doped region.

17. The semiconductor device of claim 12, wherein the second impurities have a second conductivity-type.

18. A semiconductor device comprising:
an active region extending in a first direction and including first impurities;
an ion doped region located in the active region and including second impurities;
a gate structure extending in a second direction, the second direction intersecting the first direction, wherein the gate structure is disposed on the active region and traverses the active region;
a source/drain region on the active region on at least one side of the gate structure;
a vertical power structure extending in a third direction, the third direction perpendicular to the first and second directions, wherein the vertical power structure is electrically connected to the source/drain region; and
a bottom wiring disposed below the vertical power structure and electrically connected to the vertical power structure.

19. The semiconductor device of claim 18, wherein the first impurities have a first conductivity-type, and the second impurities have a second conductivity-type.

20. The semiconductor device of claim 18, wherein the ion doped region is an insulating region.
